(19) United States
(12) Patent Application Publication
(10) Pub. No.: US 2012/0048357 A1
(43) Pub. Date: Mar. 1, 2012

(54) DYE-SENSITIZED SOLAR CELL

(75) Inventors: Shuzi HAYASE, Kitakyushi-Shi (JP); Shyam S. Pandey, Kitakyushi-Shi (JP); Yoshihiro Yamaguchi, Kitakyushi-shi (JP)

(73) Assignees: NATIONAL UNIVERSITY CORPORATION KYUSHU INSTITUTE OF TECHNOLOGY, Kitakyushu-shi (JP); NIPPON STEEL CHEMICAL CO., LTD., Kitakyushu-shi (JP)

(21) Appl. No.: 13/036,540

(22) Filed: Feb. 28, 2011

(30) Foreign Application Priority Data
Sep. 1, 2010 (JP) 2010-195240
Sep. 1, 2010 (JP) 2010-195699
Feb. 3, 2011 (JP) 2011-021390

(51) Int. Cl. H01L 31/06; H01L 51/44

(52) U.S. Cl. 136/255

(57) ABSTRACT

To provide a tandem dye-sensitized solar cell having a novel structure capable of improving the light absorption efficiency and being manufactured less expensively. A dye-sensitized solar cell 10 is configured by including, in order from the light incident side, an anode substrate 12, a first dye-carrying porous oxide semiconductor layer 14, a first electrolyte layer 16a, an electrolyte redox catalyst layer 18, a second dye-carrying porous oxide semiconductor layer 20, a porous support layer 19, a second electrolyte layer 16b, and a cathode substrate 22. The electrons extracted from a conductor layer 12b by a conductor are introduced into the cathode substrate 22, so that a battery circuit, for example, for a lighting power source is configured.

### BACKGROUND OF THE INVENTION

1. Field of the Invention

The present invention relates to a so-called tandem dye-sensitized solar cell in which porous oxide semiconductor layers carrying dyes are arranged in series along a propagation direction of incident light.

2. Description of the Related Art

A dye-sensitized solar cell is referred to as a wet-type solar cell or a Graetzel cell, and is featured by including an electrochemical cell structure which is composed typically of an iodine solution without using a silicon semiconductor. Specifically, the dye-sensitized solar cell has a simple structure in which an iodine solution, or the like, is arranged, as an electrolyte solution, between a porous semiconductor layer (porous oxide semiconductor layer), such as a titania layer, formed by baking titanium dioxide powder, or the like, onto a transparent conductive glass plate (a transparent substrate with a transparent conductive film laminated thereon: anode substrate) and then by making a dye adsorbed in the baked titanium dioxide powder, and a counter electrode made of a transparent conductive glass plate (a conductive substrate: cathode substrate). In the dye-sensitized solar cell, sunlight introduced into the solar cell from the side of the transparent conductive glass plate is absorbed, and thereby electrons are generated.

The dye-sensitized solar cell has been attracting attention as a low-cost solar cell, because the solar cell uses inexpensive materials and does not need large-scale equipment for manufacturing the solar cell.

Although a dye-sensitized solar cell having a sunlight conversion efficiency of about 11% has been reported heretofore, it has been required to further improve the sunlight conversion efficiency of the dye-sensitized solar cell, and the methods to improve the conversion efficiency have been studied from various viewpoints.

As one of the methods, a method for improving the light absorption efficiency has been studied from various aspects.

That is, various dyes for use in the dye-sensitized solar cell have hitherto been studied, but a dye which is capable of highly efficiently absorbing light of a wide wavelength range from a wavelength of 400 nm to a near-infrared or longer wavelength has not been obtained. For this reason, the light not absorbed by the porous semiconductor layer adsorbing the dye is, as it is, attributed to an absorption loss. Note that, in order to improve the light absorption efficiency, it can be considered to increase the thickness of the porous semiconductor layer adsorbing the dye, but in this case, the increase in the thickness of the porous semiconductor layer does not actually lead to an improvement in the absorption efficiency due to various reasons, and on the contrary, the absorption efficiency may be reduced.

A so-called tandem dye-sensitized solar cell, in which two stages of porous oxide semiconductor layers carrying dyes are arranged in series along a propagation direction of incident light, has been studied in order to improve the light absorption efficiency.

For example, a technique has been studied, which extracts electricity in parallel from two cells configured in such a manner that two porous semiconductor layers respectively adsorbing different dyes are laminated together, and that an electrode including an FTO (fluorine-doped tin-oxide film) is arranged between the two porous semiconductor layers (see W. Kubo et al/Journal of Photochemistry and Photobiology A Chemistry 164 (2004)).

Further, a dye-sensitized solar cell has been studied, in which a first anode having a first sensitizing dye and a second anode having a second sensitizing dye different from the first sensitizing dye are arranged separately from each other, and in which a cathode typically formed of a mesh electrode is provided between both the anodes so as to allow an electrolyte to be filled between the respective electrodes (see Japanese Patent Laid-Open No. 2008-53042).

It is reported that the incident light made incident from the side of the first anode can be efficiently used by connecting in parallel the two unit cells formed on both sides of the cathode of the cell.

Further, a dye-sensitized solar cell has been studied, in which an anode and a cathode as a counter electrode, each provided with a porous titanium oxide film adsorbing a dye, are arranged separately from each other, and in which a transparent counter electrode is provided between the anode and cathode electrodes so as to allow an electrolyte to be filled between these electrodes (see Japanese Patent Laid-Open No. 2008-53042). This configuration, in which the anode side surface of the insulating layer formed as an intermediate layer of the transparent counter electrode functions as a cathode electrode, and in which the cathode side surface of the insulating layer of the transparent counter electrode functions as an anode electrode, is thus similar to the configuration which is described in Japanese Patent Laid-Open No. 2008-53042 and in which the two unit cells formed on both sides of the transparent counter electrode are connected in parallel with each other (see an article of the Nikkei Electronics searched on March 2009, Internet, URL: http://techon.nikkeibp.co.jp:80/article/NEWS/20080306/148 570/). Note that in the article of the Nikkei Electronics, there is no disclosure other than the above-described configuration read from the drawings, and hence the material, configuration, and the like, of the transparent electrode are not clear.

Note that the present inventors have proposed a dye-sensitized solar cell, although not relating to the above-described tandem dye-sensitized solar cell. The proposed dye-sensitized solar cell is configured such that a porous semiconductor layer section is provided in each of two layers, such that a conductive layer section (collector electrode) having through holes is provided between the porous semiconductor layer sections of the two layers, and such that the conductive layer section is electrically connected with a transparent conductive film of a transparent substrate, the transparent conductive film being provided on the light incident side (see Japanese Patent Laid-Open No. 2008-16405).

With this dye-sensitized solar cell, it is possible to obtain a high conversion efficiency even when the thickness of the porous semiconductor layer is increased.

Further, an np tandem dye-sensitized solar cell has been studied, in which an anode substrate, a dye sensitized n-type semiconductor layer, an electrolyte layer, a dye sensitized p-type semiconductor layer, and a cathode substrate are arranged in this order (see Japanese Patent Laid-Open No. 2006-147280).

It is reported that, in this dye-sensitized solar cell, when the p-side conversion efficiency is improved by reducing the p-side electric resistance, the conversion efficiency of the solar cell as a whole can be improved.

However, any of the above-described conventional techniques is considered to still have large room for further improvement, in view of such drawbacks as that the light absorption efficiency of the cell needs to be further improved, that the manufacturing cost of the cell is increased due to the use of many expensive transparent conductive films in the cell structure, or that a problem may be caused when the size of the cell is increased.

The present invention has been made in view of the above described problems. An object of the present invention is to provide a tandem dye-sensitized solar cell which has a novel structure capable of improving the light absorption efficiency and being inexpensively manufactured.

### SUMMARY OF THE INVENTION

A dye-sensitized solar cell according to the present invention is featured by including, in order from the light incident side, an anode substrate, a first dye-carrying porous oxide semiconductor layer, a first electrolyte layer, an electrolyte redox catalyst layer, a second dye-carrying porous oxide semiconductor layer, a porous support layer, a second electrolyte layer, and a cathode substrate.

At this time, preferably, the dye-sensitized solar cell according to the present invention includes a transparent substrate in place of the anode substrate, and further a porous conductive metal layer arranged either in the inside of the first dye-carrying porous oxide semiconductor layer or between the first dye-carrying porous oxide semiconductor layer and the first electrolyte layer, and is configured such that the porous support layer is provided either in the inside of the second dye-carrying porous oxide semiconductor layer or on one of the sides of the second dye-carrying porous oxide semiconductor layer.

Further preferably, the dye-sensitized solar cell according to the present invention is featured in that the porous conductive metal layer has numerous through holes formed irregularly and having a deep hole shape, and also has numerous porous semiconductor particles penetrating the porous conductive metal layer so as to be in contact with the layers on both sides of the porous conductive metal layer.

Further, the dye-sensitized solar cell according to the present invention is featured by including, in order from the light incident side, an anode substrate, a first dye-carrying porous oxide semiconductor layer, a first electrolyte layer, a second dye-carrying porous oxide semiconductor layer, a porous conductive metal support layer, a second electrolyte layer and a cathode substrate.

At this time, preferably, the dye-sensitized solar cell according to the present invention includes a transparent substrate in place of the anode substrate, and further a porous conductive metal layer arranged either in the inside of the first dye-carrying porous oxide semiconductor layer or between the first dye-carrying porous oxide semiconductor layer and the first electrolyte layer, and is configured such that the porous conductive metal support layer is provided either in the inside of the second dye-carrying porous oxide semiconductor layer or on one of the sides of the second dye-carrying porous oxide semiconductor layer.

Further preferably, the dye-sensitized solar cell according to the present invention is featured in that the porous conductive metal layer has numerous through holes formed irregularly and having a deep hole shape, and also has numerous porous semiconductor particles penetrating the porous conductive metal layer so as to be in contact with the layers on both sides of the porous conductive metal layer.

Further preferably, the dye-sensitized solar cell according to the present invention is featured in that the conductor layer configuring the anode substrate includes a porous conductive metal layer.

Further preferably, the dye-sensitized solar cell according to the present invention is featured in that the dye carried by the second dye-carrying porous oxide semiconductor layer has a light absorption wavelength longer than a light absorption wavelength of the dye carried by the first dye-carrying porous oxide semiconductor layer.

The dye-sensitized solar cell according to the present invention is configured such that a first dye-carrying porous oxide semiconductor layer, a first electrolyte layer, and a cathode substrate are provided in order from the light incident side, such that an anode substrate is provided, or a transparent substrate in place of the anode substrate and further a porous conductive metal layer are provided, and such that an electrolyte redox catalyst layer, a second dye-carrying porous oxide semiconductor layer, a porous support layer, and the second electrolyte layer are further provided, or a second dye-carrying porous oxide semiconductor layer, a porous conductive metal support layer, and the second electrolyte layer are further provided. Thus, the dye-sensitized solar cell according to the present invention has an excellent light absorption efficiency. Further, since the dye-sensitized solar cell according to the present invention does not necessarily need an expensive transparent conductive film or does not need to use many expensive transparent conductive films, it is possible to reduce the manufacturing cost of the dye-sensitized solar cell.

### BRIEF DESCRIPTION OF THE DRAWINGS

FIG. 1 is a schematic diagram showing a configuration of a dye-sensitized solar cell according to a first example of the present embodiment;

FIG. 2 is a schematic diagram showing a configuration of a modification of the dye-sensitized solar cell according to the first example of the present embodiment;

FIG. 3 is a diagram showing chemical structures of a first dye (Dye2) and a second dye (Dye1);

FIG. 4 is a schematic diagram showing a configuration of a dye-sensitized solar cell according to a second example of the present embodiment;

FIG. 5A is a schematic diagram of a structure of a cell member, for explaining a manufacturing process of a method for manufacturing the porous conductive metal layer of the dye-sensitized solar cell according to the second example of the present embodiment, and for explaining a process for forming a porous semiconductor layer;

FIG. 5B is a schematic diagram of the structure of the cell member, for explaining the manufacturing process of the method for manufacturing the porous conductive metal layer of the dye-sensitized solar cell according to the second example of the present embodiment, and for explaining a process for forming a mixture layer;

FIG. 5C is a schematic diagram of the structure of the cell member, for explaining the manufacturing process of the method for manufacturing the porous conductive metal layer of the dye-sensitized solar cell according to the second example of the present embodiment, and for explaining a process for forming a conductive metal film;

FIG. 5D is a schematic diagram of the structure of the cell member, for explaining the manufacturing process of the method for manufacturing the porous conductive metal layer of the dye-sensitized solar cell according to the second example of the present embodiment, and for explaining a fine particle layer elimination process including a baking process;

FIG. 5E is a schematic diagram of the structure of the cell member, for explaining the manufacturing process of the method for manufacturing the porous conductive metal layer of the dye-sensitized solar cell according to the second example of the present embodiment, and for explaining a fine particle layer elimination process not including the baking process;

FIG. 6 is a schematic diagram showing a configuration of a dye-sensitized solar cell according to a third example of the present embodiment; and

FIG. 7 is a figure showing an SEM photograph of a Ti film, obtained from manufacturing execution example 3 of a dye-sensitized solar cell having a single cell configured similarly to the top cell of the dye-sensitized solar cell according to the example of the present embodiment.

### DESCRIPTION OF SYMBOLS

10, 10a, 40, 42 Dye-sensitized solar cell
12 Anode substrate
12a Transparent substrate
12b Conductor layer
14 First dye-carrying porous oxide semiconductor layer
16a First electrolyte layer
16b Second electrolyte layer
18 Electrolyte redox catalyst layer
19 Porous support layer
19a Porous conductive metal support layer
20 Second dye-carrying porous oxide semiconductor layer
22 Cathode substrate
24 Spacer
25 Porous semiconductor particle
26 Through hole
28 Fine particle
30 Porous conductive metal layer

### DETAILED DESCRIPTION OF THE PREFERRED EMBODIMENTS

In the following, embodiments according to the present invention (hereinafter referred to as examples of the present embodiment) will be described with reference to the accompanying drawings.

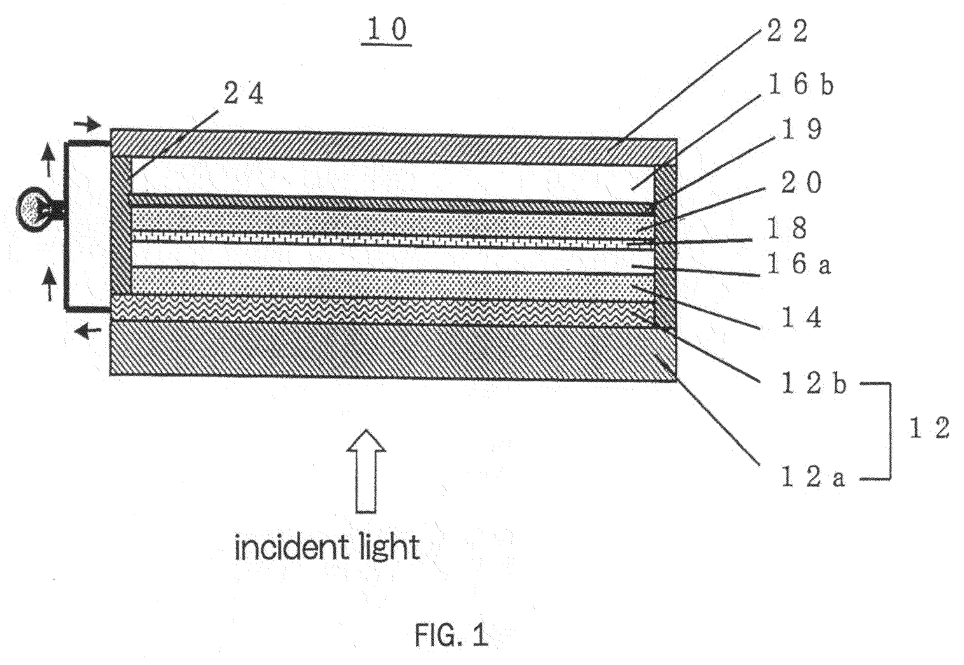

A dye-sensitized solar cell according to a first example of the present embodiment will be described with reference to FIG. 1.

A dye-sensitized solar cell 10 according to an example of the present embodiment is configured by including, in order from the light incident side, an anode substrate 12, a first dye-carrying porous oxide semiconductor layer (hereinafter may be simply referred to as a first semiconductor layer) 14 held by the anode substrate 12, a first electrolyte layer 16a, an electrolyte redox catalyst layer 18, a second dye-carrying porous oxide semiconductor layer (hereinafter may be simply referred to as a second semiconductor layer) 20, a porous support layer 19, a second electrolyte layer 16b, and a cathode substrate 22. The electrolyte redox catalyst layer 18 is carried on the surface of the second dye-carrying porous oxide semiconductor layer 20 provided on one side of the porous support layer 19, the one side facing the first electrolyte layer 16a. Note that reference numeral 24 in FIG. 1 denotes a spacer for sealing and fixing the electrolyte layers 16a and 16b, and the like.

The anode substrate 12 can be configured, for example, by a transparent substrate 12a formed of glass, a resin film, or the like, and a light-transmissive conductor layer 12b which is provided on the transparent substrate 12a.

The material of the conductor layer 12b of the anode substrate 12 is not limited in particular, and an ITO film (tin-doped indium film), an FTO film (fluorine-doped tin-oxide film), SnO₂ film, or the like, can be used as the material of the conductor layer 12b. The conductor layer 12b may also be configured to include a porous conductive metal layer together with the FTO film, or the like. As such a porous conductive metal layer, it is possible to use a layer, such as a metal mesh, a metal layer with numerous holes formed therein beforehand, or a porous metal layer formed by a thermal spraying method, a thin film forming method, or the like.

The cathode substrate 22 can be formed into a suitable configuration, such as, for example, a configuration in which a catalyst film is provided on the inner surface of a conductive metal layer.

The dyes respectively carried by the first dye-carrying porous oxide semiconductor layer 14 and the second dye-carrying porous oxide semiconductor layer 20 (hereinafter may be respectively referred to as a first dye and a second dye) are dyes which are adsorbed in the semiconductor material forming the porous semiconductor layer and which have an absorption wavelength range of 400 nm to 1000 nm. As such dyes, it is possible to list, for example, metal complexes, such as a ruthenium dye and a phthalocyanine dye, containing the COOH group, and an organic dye, such as a cyanine dye.

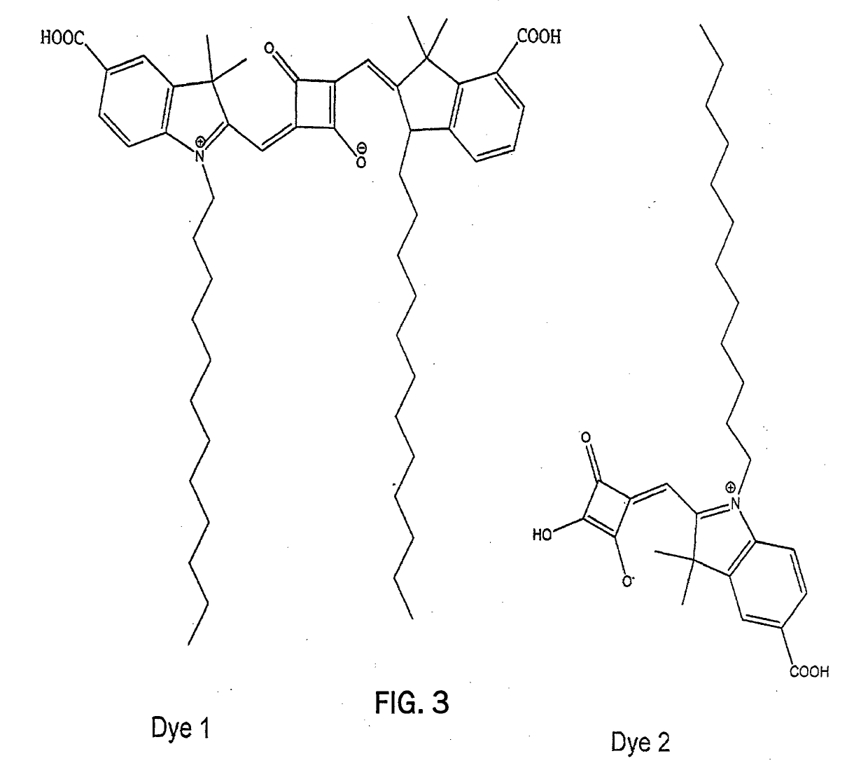

The same kind of dyes can be used as the first and second dyes. However, it is more preferred to use, as the first dye, a dye having, for example, a chemical structure of Dye 2 shown in FIG. 3 and absorbing short wavelength light which is easily lost during propagation through the cell, and to use, as the second dye, a dye having, for example, a chemical structure of Dye 1 shown in FIG. 3 and absorbing light having a longer wavelength than the wavelength of the light absorbed by the first dye.

As the semiconductor material of the porous oxide semiconductor layer which carries the dye in the first dye-carrying porous oxide semiconductor layer 14 and the second dye-carrying porous oxide semiconductor layer 20, it is possible to use an oxide of a metal, such as, for example, titanium, tin, zirconium, zinc, indium, tungsten, iron, nickel, or silver.

The porous oxide semiconductor layer is formed by baking the semiconductor material at a temperature of 300° C. or more, and more preferably at a temperature of 450° C. or more. On the other hand, the upper limit of the baking temperature is not particularly limited, but more preferably the baking temperature is set to a temperature of 550° C. or less. Further, when titanium oxide (titania) is used as the material of the porous semiconductor layer, it is preferred to bake the material at such a temperature as not to cause a shift to a rutile crystal, and to bake the material in the anatase crystalline state in which the titanium oxide is highly conductive.

The porous oxide semiconductor layers of the first dye-carrying porous oxide semiconductor layer 14 and the second dye-carrying porous oxide semiconductor layer 20 may be formed of the same semiconductor material, for example, titanium oxide. However, it is more preferred that the porous oxide semiconductor layer of the first dye-carrying porous oxide semiconductor layer 14 is formed of a titanium oxide, and that the porous oxide semiconductor layer of the second dye-carrying porous oxide semiconductor layer 20 is formed of a tin oxide. This is because the energy level of the conduction band of the tin oxide is lower than the energy level of the conduction band of titanium oxide and corresponds to (can be easily adapted to) the LUMO of the dye absorbing long wavelength light.

The thickness of the porous oxide semiconductor layer of each of the first dye-carrying porous oxide semiconductor layer 14 and the second dye-carrying porous oxide semiconductor layer 20 is not limited in particular, but preferably is set to a thickness of 14 μm or less.

The first and second electrolyte layers 16a and 16b contain iodine, lithium ions, an ionic liquid, t-butyl pyridine, and the like. For example, in the case of using iodine, it is possible to use an oxidation-reduction agent composed of a combination of iodide ions and iodine. The oxidation-reduction agent contains a suitable solution which can dissolve the oxidation-reduction agent.

The material of the porous support layer 19 is not limited in particular, as long as the material has sufficient light transmissivity and porosity enabling the electrolyte solution to pass therethrough, and can surely support the second dye-carrying porous oxide semiconductor layer 20 even when the material has a thin film thickness. The porous support layer 19 may be formed of a suitable inorganic material, or may also be formed of a suitable metal material.

The electrolyte redox catalyst layer 18 carried by the second dye-carrying porous oxide semiconductor layer 20 provided on the porous support layer 19 oxidizes and reduces the oxidation-reduction agent contained in the electrolyte layers 16a and 16b (for example, reduces I₃-to I- in the case where the oxidation-reduction agent contains iodine), to promote the transfer of electrons to the first dye-carrying porous oxide semiconductor layer 14, and can also be simply referred to as a catalyst layer. When the electrolyte redox catalyst layer 18 is not provided, I₃- cannot be reduced to I- and is accumulated, so that the dye which has lost electrons cannot be sufficiently reduced and thereby an excellent efficiency cannot be obtained. The electrolyte redox catalyst layer 18 can be formed of a material, such as, for example, platinum, a conductive polymer, and carbon. The electrolyte redox catalyst layer 18 can be formed by a suitable film forming method, such as, for example, a sputtering method.

The electrons extracted from the conductor layer 12b by a conductor are introduced into the cathode substrate 22, so that a battery circuit, for example, as a lighting power source is configured.

Structurally, the solar cell 10 is a so-called tandem structure (tandem type) cell in which the first semiconductor layer 14 and the second semiconductor layer 20 are laminated in the propagation direction of light. From the viewpoint of cell operation, the solar cell 10 can be referred to as series-connected cells in which two unit cells are arranged in series by providing a pair of the first semiconductor layer 14 and the first electrolyte layer 16a, and a pair of the second semiconductor layer 20 and the second electrolyte layer 16b.

In this case, when the member corresponding to the porous support layer 19 is a non-porous member, for example, a transparent conductive film, or a metal film, which impedes the circulation of the electrolyte, and thereby, when the amount of current flowing through the cell (referred to as cell 1) configured by including the first dye-carrying porous oxide semiconductor layer 14 is not equal to the amount of current flowing through the cell (referred to as cell 2) configured by including the second dye-carrying porous oxide semiconductor layer 20, for example, when the amount of current flowing through the cell 2 is smaller than the amount of current flowing through the cell 1, the smaller amount of current becomes a rate-limiting factor and thereby the performance of the cell is lowered. In an extreme case where a dye for long wavelength light absorption is used for the cell 2, when light lacking in the long wavelength components is made incident on the cell 2, the current does not flow through the cell 2.

On the contrary, with the dye-sensitized solar cell 10 according to the example of the present embodiment, the circulation of the electrolyte solution between the cell 1 and the cell 2 is secured, and hence it is not necessary to take into consideration the balance in the light absorption amount between the dye 1 and the dye 2. Even when no current flows through the cell 2, the dye-sensitized solar cell 10 functions.

With the dye-sensitized solar cell 10 according to the first example of the present embodiment as described above, it is possible to obtain a high voltage at a high power generation efficiency. Further, the electrode can be formed less expensively as compared with the case of using a transparent conductive film, such as an FTO film, and hence it is possible to manufacture the cell at low cost. Further, in the case where the size of the cell is increased, the power loss caused by the electrode is smaller as compared with the case of using the FTO film, and the like.

Here, a modification of the dye-sensitized solar cell 10 according to the first example of the present embodiment will be described.

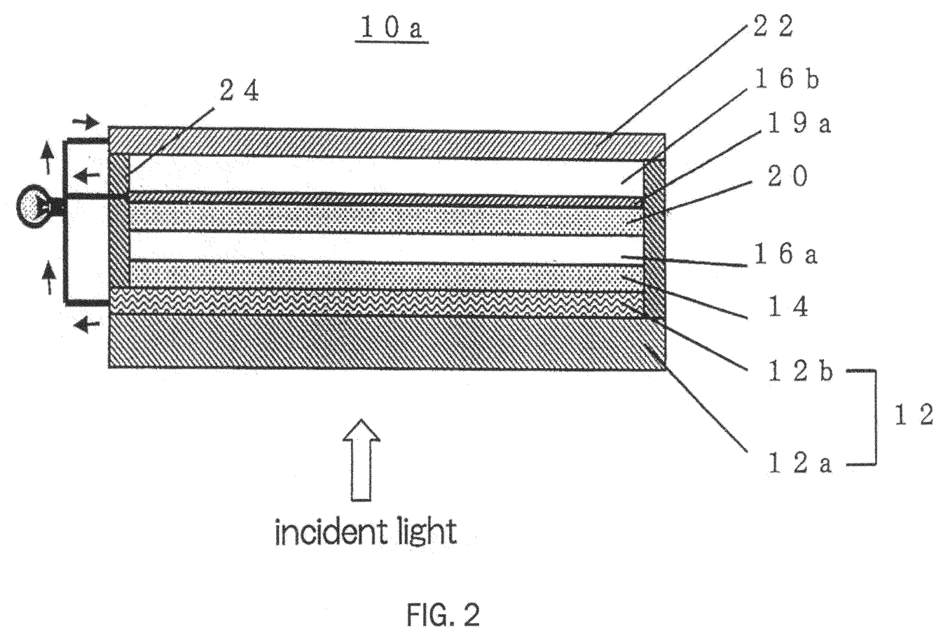

The fundamental configuration of a dye-sensitized solar cell 10a according to a modification shown in FIG. 2 is the same as the configuration of the dye-sensitized solar cell 10. For this reason, the duplicated description of the respective members is omitted.

The dye-sensitized solar cell 10a is different from the dye-sensitized solar cell 10 in that the electrolyte redox catalyst layer 18 of the dye-sensitized solar cell 10 is omitted, and in that a porous conductive metal support layer 19a is provided in place of the porous support layer 19.

The porous conductive metal support layer 19a functions as the porous support layer 19, and also has a function corresponding to the function of the electrolyte redox catalyst layer 18.

The porous conductive metal support layer 19a can be formed by using a material such as a metal mesh, a metal layer with numerous holes formed therein beforehand, and a porous metal layer formed by a thermal spraying method, a thin film forming method, or the like. Thereby, the porous conductive metal support layer 19a can be formed less expensively.

With the dye-sensitized solar cell 10a according to the modification as described above, the configuration of which is simplified to an extent corresponding to the omission of the electrolyte redox catalyst layer 18, it is possible to obtain the same effect as that obtained with the dye-sensitized solar cell 10.

Specific manufacturing examples of the dye-sensitized solar cells 10 and 10a will be described below.

The effects of the dye-sensitized solar cells 10 and 10a can be easily understood from the following examples configured similarly to the dye-sensitized solar cells 10 and 10a.

### Manufacturing Example 1 of Dye-Sensitized Solar Cell According to First Example of Present Embodiment

An FTO film (surface resistance: 10Ω/□) is formed on a transparent glass substrate. Further, a titania paste is applied on the FTO film and then dried at 450° C. for 30 minutes, so that a porous titania layer having a thickness of 2 μm is manufactured. The first electrode section is manufactured by making the first dye (Dye2) adsorbed in the porous titania layer. On the other hand, a titanium film is formed by sputtering titanium on a mesh stainless steel substrate (thickness: 25 μm) having a mesh of 20 μm diameter, and then a titanium film is further formed by an arc plasma method while introducing oxygen, so that a stainless steel mesh structure having a protected surface is manufactured. A titania paste is applied to the surface of one side of the mesh structure, and then dried at 450° C. for 30 minutes, so that a porous titania layer having a thickness of 2 μm is manufactured. After platinum is sputtered on the surface of the porous titania layer of the mesh structure, the second electrode section is manufactured by making the second dye (Dye1) adsorbed in the titania layer. As the electrolyte solution, a gel electrolyte solution formed by impregnating an electrolyte solution into a porous PTFE (Polytetrafluoroethylene) film (thickness: 50 μm, porosity: 80%) is used. The counter electrode is manufactured by sputtering platinum on a titanium film. These are successively laminated, in other words, the counter electrode is arranged to face the surface of the porous titania layer of the second electrode section, so that a solar cell is manufactured.

### Manufacturing Example 2 of Dye-Sensitized Solar Cell According to First Example of Present Embodiment

An FTO film (surface resistance: 10Ω/μ) is formed on a transparent glass substrate. Further, a titania paste is applied on the FTO film, and then dried at 450° C. for 30 minutes, so that a porous titania layer having a thickness of 2 μm is manufactured. The first electrode section is manufactured by making the first dye adsorbed in the porous titania layer. On the other hand, a titanium film is formed by sputtering titanium on a mesh stainless steel substrate (thickness: 25 μm) having a mesh of 20 μm diameter, and then a titanium film is further formed by an arc plasma method while introducing oxygen, so that a stainless steel mesh structure having a protected surface is manufactured. A titania paste is applied to the surface of one side of the mesh structure, and then dried at 450° C. for 30 minutes, so that a porous titania layer having a thickness of 2 μm is manufactured. The second electrode section is manufactured by making the second dye adsorbed in the titania layer. As the electrolyte solution, a gel electrolyte solution formed by impregnating an electrolyte solution into a porous PTFE film (thickness: 50 μm, porosity: 80%) is used. The counter electrode is manufactured by sputtering platinum on a titanium film. These are successively laminated, in other words, the counter electrode is arranged to face the surface of the porous titania layer of the second electrode section, so that a solar cell is manufactured.

### Manufacturing Execution Example 1 of Dye-Sensitized Solar Cell Having Structure Similar to Dye-Sensitized Solar Cell According to First Example of Present Embodiment

An FTO film (surface resistance: 10Ω/□) was formed on a transparent glass substrate. Further, a titania paste was applied on the FTO film, and then dried at 450° C. for 30 minutes, so that a porous titania layer having a thickness of 2 μm was formed. The first electrode section was manufactured by making the first dye (Dye2) adsorbed in the porous titania layer. On the other hand, a titanium film was formed by sputtering titanium on a mesh stainless steel substrate (thickness: 25 μm) having a mesh of 20 μm diameter. Then, a titanium film was further formed by an arc plasma method while introducing oxygen, so that a stainless steel mesh structure having a protected surface was manufactured. A titania paste was applied to coat one surface of the mesh structure, and then dried at 450° C. for 30 minutes, so that a porous titania layer having a thickness of 2 μm was manufactured. After platinum was sputtered on the surface of the mesh structure, on which surface the porous titania layer was not formed, the second electrode section was manufactured by making the second dye (Dye1) adsorbed in the titania layer. As the electrolyte solution, a gel electrolyte solution formed by impregnating an electrolyte solution into a porous PTFE (Polytetrafluoroethylene) film (thickness: 50 μm, porosity: 80%) was used. The counter electrode was manufactured by sputtering platinum on a titanium film. These were successively laminated, in other words, the counter electrode was arranged to face the surface of the porous titania layer of the second electrode section, so that a solar cell was manufactured.

In the obtained solar cell, as the performance of the cell (integrated cell) configured by electrically connecting the first electrode section with the counter electrode, the following values were obtained: Voc=0.81 V, Jsc=5.2 mA/cm², FF=0.67, and Efficiency=2.8%. Further, as the performance of the cell (single cell 1) manufactured separately from the integrated cell and configured by the first electrode section and the counter electrode, the following values were obtained: Voc=0.4 V, Jsc=5.4 mA/cm², FF=0.70, and Efficiency=1.5%. On the other hand, as the performance of the cell (single cell 2) manufactured separately from the integrated cell and configured by the second electrode section and the counter electrode, the following values were obtained: Voc=0.42 V, Jsc=4.9 mA/cm², FF=0.70, and Efficiency=1.44%. It was seen that the value of Voc of the integrated cell was increased to a value substantially equivalent to the sum of the values of Voc of the single cell 1 and the single cell 2, as compared with the case having only the single cell 1, which approximately corresponds to the conventional cell. It was seen that the peaks of the IPCE value of the integrated cell were obtained at wavelengths respectively corresponding to the peak of the IPCE value of the single cell 1 having the absorption wavelength of 500 nm and the peak of the IPCE value of the single cell 2 having the absorption wavelength of 700 nm.

### Manufacturing Execution Example 2 of Dye-Sensitized Solar Cell Having Structure Similar to Dye-Sensitized Solar Cell According to First Example of Present Embodiment

An FTO film (surface resistance: 10Ω/μ) was formed on a transparent glass substrate. Further, a titania paste was applied on the FTO film, and then dried at 450° C. for 30 minutes, so that a porous titania layer having a thickness of 2 μm was formed. The first electrode section was manufactured by making the first dye adsorbed in the porous titania layer. On the other hand, a titanium film was formed by sputtering titanium on a mesh stainless steel substrate (thickness: 25 μm) having a mesh of 20 μm diameter. Then, a titanium film was further formed by an arc plasma method while introducing oxygen, so that a stainless steel mesh structure having a protected surface was manufactured. A titania paste was applied to coat one surface of the mesh structure, and then dried at 450° C. for 30 minutes, so that a porous titania layer having a thickness of 2 μm was manufactured. The second electrode section was manufactured by making the second dye adsorbed in the titania layer. As the electrolyte solution, a gel electrolyte solution formed by impregnating an electrolyte solution into a porous PTFE film (thickness: 50 μm, porosity: 80%) was used. The counter electrode was manufactured by sputtering platinum on a titanium film. These were successively laminated, in other words, the counter electrode was arranged to face the surface of the porous titania layer of the second electrode section, so that a solar cell was manufactured.

In the obtained solar cell, as the performance of the cell (integrated cell) configured by electrically connecting the counter electrode with each of the first electrode section and the second electrode section, the following values were obtained: Voc=0.4 V, Jsc=12.1 mA/cm², FF=0.60, and Efficiency=2.9%. Further, as the performance of the cell (single cell 1) manufactured separately from the integrated cell and configured by the first electrode section and the counter electrode, the following values were obtained: Voc=0.4 V, Jsc=5.4 mA/cm², FF=0.70, and Efficiency=1.5%. On the other hand, as the performance of the cell (single cell 2) manufactured separately from the integrated cell and configured by the second electrode section and the counter electrode, the following values were obtained: Voc=0.42 V, Jsc=4.9 mA/cm², FF=0.70, and Efficiency=1.44%. It was seen that the value of Jsc of the integrated cell was increased to a value substantially equivalent to the sum of the values of Jsc of the single cell 1 and the single cell 2 as compared with the case having only the single cell 1, which approximately corresponds to the conventional cell. It was seen that the peaks of the IPCE value of the integrated cell were obtained at wavelengths respectively corresponding to the peak of the IPCE value of the single cell 1 having the absorption wavelength of 500 nm and the peak of the IPCE value of the single cell 1 having the absorption wavelength of 700 nm.

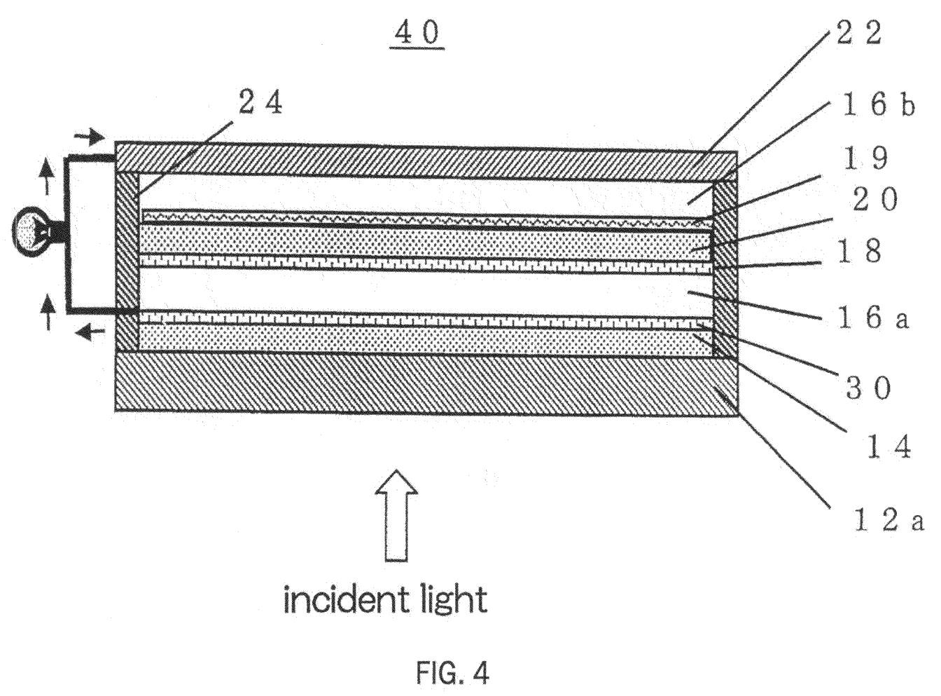

Next, a dye-sensitized solar cell according to a second example of the present embodiment will be described with reference to FIG. 4. In a second example and a third example as will be further described below, the description of the same components as those of the first example may be omitted.

A dye-sensitized solar cell 40 according to the second example of the present embodiment is configured by providing, in order from the light incident side, a transparent substrate 12a, a first dye-carrying porous oxide semiconductor layer (hereinafter may be simply referred to as a first semiconductor layer) 14 arranged on the transparent substrate 12a, a porous conductive metal layer 30 arranged on the surface of the first dye-carrying porous oxide semiconductor layer 14, the surface being on the side opposite to the side of the transparent substrate 12a (the upper surface of the first dye-carrying porous oxide semiconductor layer 14), a first electrolyte layer 16a, an electrolyte redox catalyst layer 18, a second dye-carrying porous oxide semiconductor layer (hereinafter may be simply referred to as a second semiconductor layer) 20, a porous support layer 19 arranged on one side of the second dye-carrying porous oxide semiconductor layer 20, the one side being the side of a second electrolyte layer 16b, the second electrolyte layer 16b, and a cathode substrate 22. The cathode substrate 22 is a substrate (conductive substrate) having a conductive film. Note that reference numeral 24 denotes a spacer for sealing and fixing the electrolyte layers 16a and 16b, and the like.

The transparent substrate 12a may be, for example, a glass plate, or a plastic plate. When a plastic plate is used, it is possible to list, as the material of the plastic plate, for example, PET, PEN, polyimide, cured acrylic resin, cured epoxy resin, cured silicone resin, various engineering plastics, a cyclic polymer obtained by metathesis polymerization, and the like.

As the porous conductive metal layer 30, a suitable material can be used, and for example, a conductive mesh metal, a conductive metal thin film, and the like, can be used. The conductive metal thin film can be formed on the first dye-carrying porous oxide semiconductor layer 14 by a simple method, such as an application method, or more preferably, by a sputtering method.

As the material of the porous conductive metal layer 30, a suitable metal can be selected and used, as long as the material has suitable conductive properties. Here, the metal not only means a single metal, but also includes a metal compound, such as a metal oxide, and an alloy.

The porous conductive metal layer 30 may also be configured by making the surface of the metal coated with a dense oxide semiconductor layer, for example, a titania layer. However, from a viewpoint of surely preventing the corrosion of the porous conductive metal layer 30 due to the electrolyte solution containing the oxidation-reduction agent, such as iodine, it is more preferred to use a corrosion-resistant metal as the material of the porous conductive metal layer 30. As the corrosion resistant metal, tungsten (W), titanium (Ti), nickel (Ni), a mixture of these metals, or a compound of these metals can be suitably used. However, other than these metals, for example, a metal with a passivated surface can also be used.

From a viewpoint of reducing the area resistance of the porous conductive metal layer 30, the porous conductive metal layer 30 preferably has a thicker thickness and is formed to have a thickness of 100 nm or more, and more preferably a thickness of 200 nm or more. The upper limit of the thickness of the porous conductive metal layer 30 is not limited in particular.

The porous conductive metal layer 30 is electrically connected to an external electrode (collector electrode).

When the porous conductive metal layer 30 is provided, a so-called TCO-less configuration can be obtained by eliminating the conductor layer, such as ITO film (tin-doped indium film) and FTO film (fluorine-doped tin-oxide film), or SnO₂ film, which is usually provided on the transparent substrate 12a, and thereby the transmission and absorption efficiency of light can be increased.

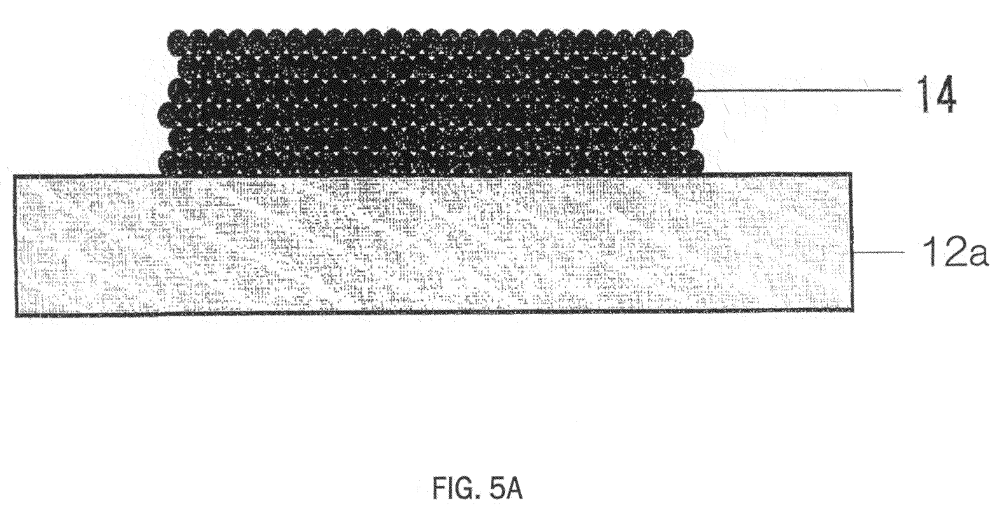

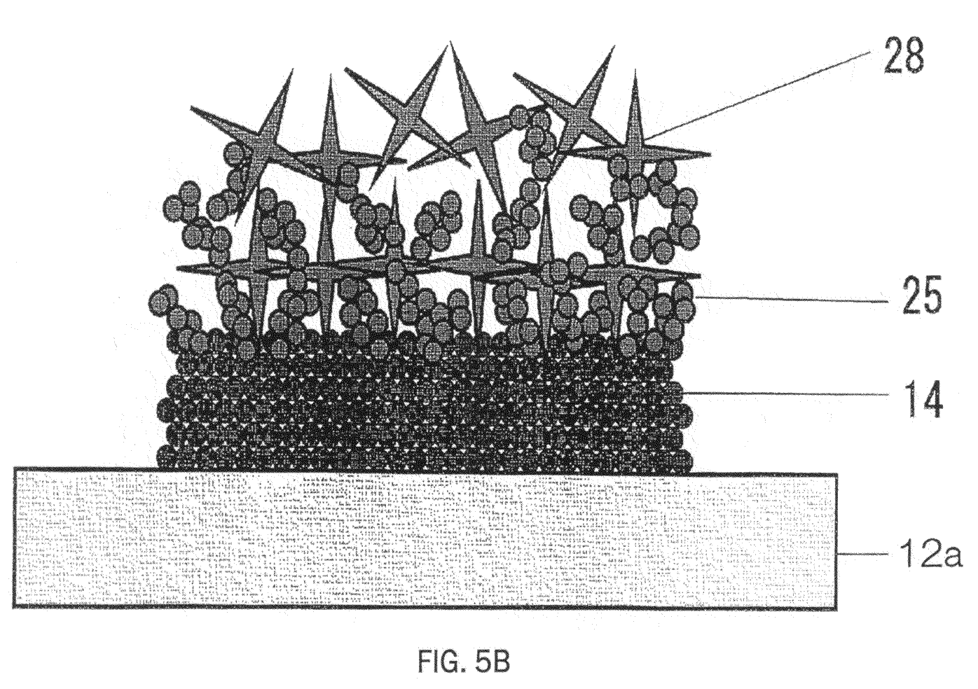

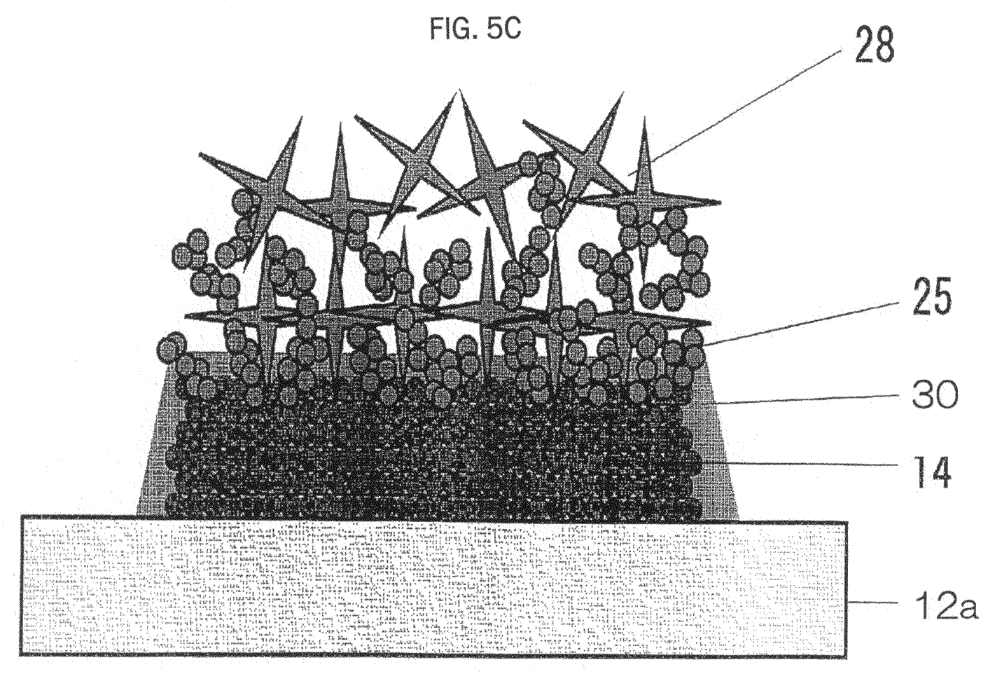

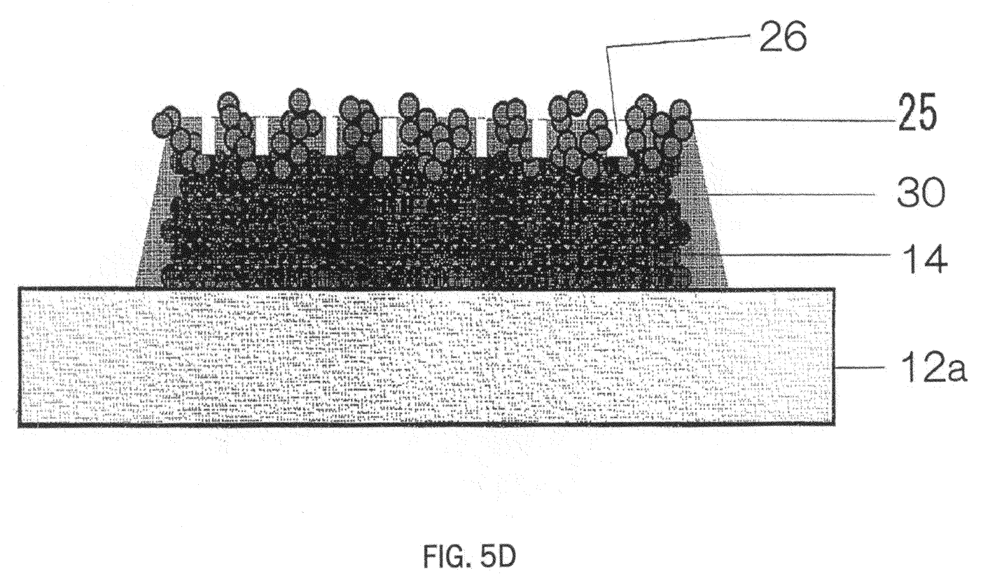

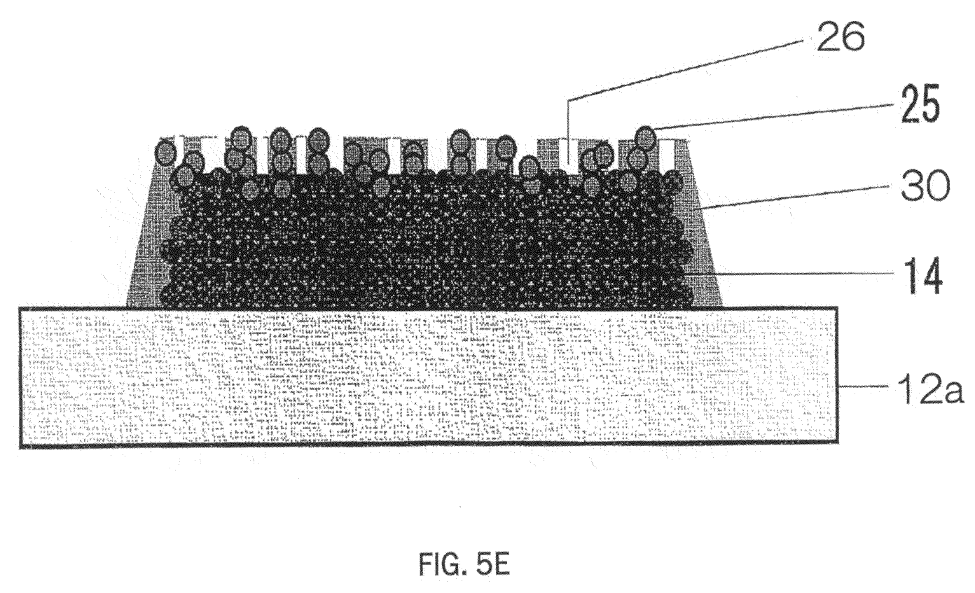

It is more preferred that, as shown in FIG. 5E, the porous conductive metal layer 30 has numerous through holes 26 formed irregularly and having a deep hole shape, and has numerous porous semiconductor particles 25 penetrating the porous conductive metal layer 30 to be in contact with the layers (first dye-carrying porous oxide semiconductor layer 14 in FIG. 1) on both sides of the porous conductive metal layer 30. Here, the deep hole-shaped through hole 26 means a hole which, even in the case of the porous conductive metal layer 30 having a thick thickness, has a small diameter relative to the thickness and has a depth deep enough to penetrate the porous conductive metal layer 30. The deep hole-shaped through hole 26 means, for example, a hole with a long cylindrical shape having a depth dimension several times or several ten times the diameter of the hole.

Specifically, the numerous through holes 26 are formed and irregularly arranged depending on manufacturing conditions. However, a suitable number of the through holes 26 may be sufficient, as long as the through holes 26 enable the electrolyte solution to be sufficiently penetrated and permeated. The length (depth) of the through hole 26 is determined in correspondence with the thickness of the porous conductive metal layer 30, but is preferably set to 100 nm to 5 μm. The deep hole-shaped through holes 26 enable the electrolyte solution to be more efficiently diffused to the first dye-carrying porous oxide semiconductor layer 14 as compared with irregularly formed small holes as described in W. Kubo et al/Journal of Photochemistry and Photobiology A Chemistry 164 (2004). The diameter of the through hole 26 is not limited in particular, but is set preferably to 0.1 μm to 5 μm, and more preferably to 0.2 μm to 3 μm.

The porous conductive metal layer 30 has the numerous porous semiconductor particles 25 penetrating the through holes 26 so that one end of the porous semiconductor particle 25 is exposed to the first electrolyte layer 16a and the other end of the porous semiconductor particle 25 is joined with the first dye-carrying porous oxide semiconductor layer 14.

As the material of the porous semiconductor particle 25, a material, which is the same as or different from the material of the first dye-carrying porous oxide semiconductor layer 14, may be used. Further, as for the particle diameter of the porous semiconductor particle 25, particles, which have a particle diameter approximately equal to or different from the particle diameter of the material of the first dye-carrying porous oxide semiconductor layer 14, may also be used.

The shape of the porous semiconductor particle 25 is not limited in particular. For example, an anisotropically shaped particle having a needle shape or an elliptic cylindrical shape can be used.

In order to make the porous semiconductor particles 25 surely penetrate the porous conductive metal layer 30, it is preferred that the porous semiconductor particles 25 are prepared to have a longitudinal dimension of 100 nm or more.

As the porous semiconductor particle 25, aggregates of particles having a primary particle diameter of 10 to 40 nm can be used.

It is preferred that the porous semiconductor particles 25 are burned at a temperature of 300 to 550° C.

Here, a suitable manufacturing method of the porous conductive metal layer 30 will be described with reference to FIG. 5A to FIG. 5E.

First, the material of the first dye-carrying porous oxide semiconductor layer (first semiconductor layer) 14 is applied to the transparent substrate 12a, so that the first semiconductor layer 14 is formed (see FIG. 5A). Here, the first semiconductor layer 14 means the layer formed by baking the applied material of the first semiconductor layer 14.

Then, a mixture, for example, in a paste state is prepared by mixing the porous semiconductor particles (particles used as the material of the porous semiconductor layer) 25 with fine particles 28 having a shape anisotropy and capable of being removed by heating or solvent washing, and is then arranged on the first semiconductor layer 14 so that a mixture layer is formed (mixture layer forming process, see FIG. 5B). At this time, when a material having, for example, a fine fiber shape is independently used as the fine particle 28, the material may be formed into a lump (grain-sized aggregate). However, when the material is used together with the porous semiconductor particles 25, it is possible to obtain an effect of suppressing the aggregation of the material. The mixture layer can be formed, for example, by dispersing the slurry of the mixture on the porous semiconductor layer 14 by using an electrospray. At this time, the mixture layer may be subsequently subjected to baking treatment at a temperature of about 300 to about 550° C.

Then, the porous conductive metal layer 30 is formed on the mixture layer (porous conductive metal layer forming process, see FIG. 5C). At this time, the mixture of the fine particles 28 having the shape anisotropy and the porous semiconductor particles 25 penetrates the porous conductive metal layer 30 so that the upper end of the mixture is exposed and further a part of the mixture is fully exposed as shown in FIG. 5C. Note that, although the mixture layer is illustrated to have a thickness about ten times the thickness of the porous conductive metal layer 30 in order to facilitate understanding of the present invention, the thickness of the mixture layer from one to several times the thickness of the porous conductive metal layer 30 is sufficient.

Then, the fine particles 28 are eliminated by heating or solvent washing (fine particle elimination process, see FIG. 5D and FIG. 5E). Thereby, the numerous deep hole-shaped through holes 26 are irregularly formed in the porous conductive metal layer 30. Further, at this time, one end of the porous semiconductor particles 25, which are not eliminated by the heating or the solvent washing, is joined with the porous semiconductor layer 14, and the other end of the porous semiconductor particles 25 is exposed from the porous conductive metal layer 30. Note that, when the thickness of the mixture layer is larger than the thickness of the porous conductive metal layer 30, a porous semiconductor particle layer joined with the porous semiconductor particles 25 is partially formed on the porous conductive metal layer 30. The partially formed porous semiconductor particle layer may be left as it is, or may be removed by a suitable method.

Note that FIG. 5D shows a porous conductive metal layer forming process including the process of baking the mixture layer, and FIG. 5E shows a conductive metal film forming process not including the process of baking the mixture layer.

Then, the first dye-carrying porous oxide semiconductor layer 14 is obtained by making the dye adsorbed in the first semiconductor layer 14.

As the material of the fine particles 28 used in the manufacturing method of the porous conductive metal layer 30, a material is used, which, when the fine particle layer is removed by heating, is thermally decomposed and removed at a temperature not thermally damaging the previously formed layers, such as the first semiconductor layer 14. Thus, the mixture layer is baked at a temperature near the thermal decomposition temperature of the material. The temperature not damaging the previously formed layers, such as the first semiconductor layer 14, means, for example, a temperature sufficiently lower than 500° C., and more preferably a temperature of 200° C. or less. Thereby, the thermal effect on the porous conductive metal layer 30, which may be caused when the porous conductive metal layer 30 is heated at a temperature of, for example, 500° C. or more, is also reduced. Further, when the fine particle layer is removed by solvent washing, a solvent not damaging the previously formed layers, such as the porous semiconductor layer, is used in combination with a fine particle material which can be easily removed by washing using the solvent.

Such fine particle material is not limited in particular, but a resin, such as polystyrene and poly methyl methacrylate, and a metal oxide, such as zinc oxide, can be preferably used as the fine particle material. Further, the solvent used for the solvent washing is not limited in particular, and may be suitably selected in correspondence with the fine particle material. For example, an organic solvent, such as toluene, which can dissolve a resin, and an acid, such as dilute hydrochloric acid, which can dissolve a metal, can be used for the solvent washing.

As the fine particles 28 formed of the above-described material, fine particles having a shape anisotropy are used. As such fine particles, it is preferred to use needle-like fine particles, or fine particles which have numerous legs each having as its tip a vertex of a polyhedron. However, the shape of the fine particles is not limited to these, and for example, fine particles having an elliptic ball shape (for example, a bean shape and a rugby ball shape) may also be used.

When fine particles having numerous legs each having, as its tip, a vertex of a polyhedron are used as the fine particles 28, it is preferred that the fine particles have such a size that, for example, even when only one layer of the fine particles is formed on the first semiconductor layer 14 by spraying, the fine particles can form the through holes by surely penetrating the porous conductive metal layer which is formed on the fine particles so as to have a suitable thickness. The size of such fine particle is different in correspondence with the thickness of the porous conductive metal layer 30, but is preferably set to, for example, 1 to 30 μm.

On the other hand, when needle-like fine particles or elliptic ball-like fine particles are used as the fine particles 28, the needle-like fine particles, or the like, can be stood up or erected on the first semiconductor layer 14 by being sprayed by, for example, an electrospray method. For this reason, the size of such needle-like fine particles, or the like, is not limited in particular. However, it is preferred that the needle-like fine particles, or the like, have a suitable size corresponding to the thickness of the porous conductive metal layer 30 and are sprayed on the first semiconductor layer 14 so as to overlap with each other. The size of the needle-like fine particles, or the like, can be set to a size similar to the size of the above-described fine particles having numerous legs each having, as its tip, the vertex of the polyhedron.

When the fine particles 28 having the shape anisotropy are arranged on the first semiconductor layer 14 and then removed, deep holes are formed also in the first semiconductor layer 14. Thus, the electrolyte solution is excellently penetrated and diffused in the first semiconductor layer 14 via the deep holes communicating with the holes penetrating the porous conductive metal layer 30.

In the dye-sensitized solar cell 40 according to the second example of the present embodiment, the electrons extracted from the porous conductive metal layer 30 by a conductor are introduced into the cathode substrate 22, so that a battery circuit, for example, for a lighting power source is configured.

In this case, when the member corresponding to the porous support layer 19 is a non-porous member, for example, a transparent conductive film, and a metal film, which impedes the circulation of the electrolyte, and thereby, when the amount of current flowing through the cell (top cell referred to as cell 1) configured by including the first dye-carrying porous oxide semiconductor layer 14 is not equal to the amount of current flowing through the cell (bottom cell referred to as cell 2) configured by including the second dye-carrying porous oxide semiconductor layer 20, for example, when the amount of current flowing through the cell 2 is smaller than the amount of current flowing through the cell 1, the smaller amount of current becomes a rate-limiting factor and thereby the performance of the cell is lowered. In an extreme case where a dye for long wavelength light is used for the cell 2, when light lacking in the long wavelength components is made incident on the cell 2, the current does not flow through the cell 2.

On the contrary, with the dye-sensitized solar cell 40 according to the second example of the present embodiment, the circulation of the electrolyte solution between the cell 1 and the cell 2 is secured, and hence it is not necessary to take into consideration the balance in the light absorption amount between the dye 1 and the dye 2. Even when no current flows through the cell 2, the dye-sensitized solar cell 40 functions.

With the dye-sensitized solar cell 40 according to the second example of the present embodiment as described above, it is possible to obtain a high voltage at a high power generation efficiency. Further, the electrode can be formed less expensively as compared the case where the transparent conductive film, such as FTO film, is used, and hence it is possible to manufacture the cell at low cost. Further, in the case where the size of the cell is increased, the power loss caused by the electrode is smaller as compared with the case where the FTO film, and the like, is used for the electrode.

Here, a modification of the dye-sensitized solar cell 40 according to the second example of the present embodiment will be described.

The porous conductive metal layer 30 may be arranged in the inside of the first dye-carrying porous oxide semiconductor layer 14. That is, the dye-sensitized solar cell 40 may be configured such that the porous conductive metal layer 30 is sandwiched between a part of the first dye-carrying porous oxide semiconductor layer 14 and the remaining part of the first dye-carrying porous oxide semiconductor layer 14.

Further, the dye-sensitized solar cell 40 may also be configured such that the porous support layer 19 is arranged in the inside of the second dye-carrying porous oxide semiconductor layer 20, that is, such that the porous support layer 19 is sandwiched between a part of the second dye-carrying porous oxide semiconductor layer 20 and the remaining part of the second dye-carrying porous oxide semiconductor layer 20. Further, the porous support layer 19 may also be arranged on one side of the second dye-carrying porous oxide semiconductor layer 20, the one side being the side of the electrolyte redox catalyst layer 18.

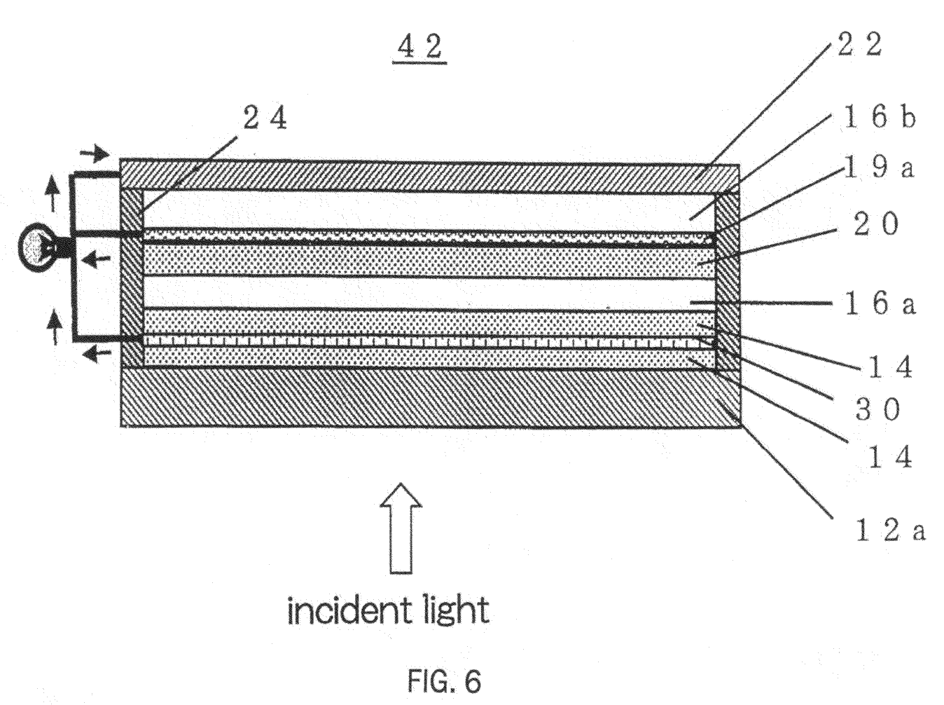

Next, a dye-sensitized solar cell 42 according to a third example of the present embodiment will be described with reference to FIG. 6.

The description of the same components of the dye-sensitized solar cell 42 as the components of the dye-sensitized solar cell 40 is omitted.

The dye-sensitized solar cell 42 according to the third example of the present embodiment is different from the dye-sensitized solar cell 40 in that the porous conductive metal layer 30 is arranged to be sandwiched between a part of the first dye-carrying porous oxide semiconductor layer 14 and the remaining part of the first dye-carrying porous oxide semiconductor layer 14, in that the porous conductive metal support layer 19a is provided on one side of the second dye-carrying porous oxide semiconductor layer 20, the one side being the side of the second electrolyte layer 16b, and in that the electrolyte redox catalyst layer 18 is not provided.

As the material of the porous conductive metal support layer 19a, it is possible to use a material, such as a metal mesh, a metal layer with numerous holes formed therein beforehand, and a porous metal layer formed by a thermal spraying method or a thin film forming method. Thereby, the porous conductive metal support layer 19a can be formed less expensively.

The dye-sensitized solar cell 42 may also be configured such that the porous conductive metal support layer 19a is arranged in the inside of the second dye-carrying porous oxide semiconductor layer 20, that is, the porous conductive metal support layer 19a is sandwiched between a part of the second dye-carrying porous oxide semiconductor layer 20 and the remaining part of the second dye-carrying porous oxide semiconductor layer 20. Further, the porous conductive metal support layer 19a may also be arranged on one side of the second dye-carrying porous oxide semiconductor layer 20, the one side being the side of the first electrolyte layer 16a.

With the dye-sensitized solar cell 42 according to the third example of the present embodiment, the configuration of which is simplified to an extent corresponding to the omission of the electrolyte redox catalyst layer 18, it is possible to obtain substantially the same efficiency as that obtained with the dye-sensitized solar cell 10a.

Specific manufacturing examples of the dye-sensitized solar cells 40 and 42 will be described below.

The effects of the dye-sensitized solar cells 40 and 42 can be easily understood from the following examples configured similarly to the dye-sensitized solar cells 40 and 42.

### Manufacturing Example of Dye-Sensitized Solar Cell According to Second Example of Present Embodiment

A titania paste is applied on a transparent glass substrate, and then dried at 450° C. for 30 minutes, so that a porous titania layer having a thickness of 2 μm is manufactured. A slurry having a mixture composition obtained by mixing zinc oxide fibers having tetrapod (registered trademark, hereinafter the same) type crystal structure (product name: Panatetra, average fiber length in fiber portion: about 10 μm, average fiber diameter: about 1 μm, made by Amtec Co., Ltd.) with titanium oxide fine particles (product name: AEROXIDE (registered trademark) TiO2P25, average particle diameter of primary particle: about 20 nm, aggregate size: 200 nm, made by Japan Aerosil Co., Ltd.) is dispersed by an electrospray method on the surface of the porous titania layer. The composition ratio of the mixture of zinc oxide fibers and titania particles is adjusted to 50:50. After the dispersion process using the electrospray, the mixture is baked at a temperature of 500° C. for 30 minutes. Thereafter, a Ti film (Ti layer) is formed by a sputtering method (film thickness: 300 nm). The remaining tetrapod type crystal fibers are removed by being rinsed with dilute hydrochloric acid, so that a conductive Ti layer is formed. The first electrode section is manufactured by making the first dye (Dye2) adsorbed in the porous titania layer.

On the other hand, a titanium film is formed by sputtering titanium on a mesh stainless steel substrate (thickness: 25 μm) having a mesh of 20 μm diameter, and then a titanium film is further formed by an arc plasma method while introducing oxygen, so that a stainless steel mesh structure having a protected surface is manufactured. A titania paste is applied to the surface of one side of the mesh structure, and is then dried at 450° C. for 30 minutes, so that a porous titania layer having a thickness of 2 μm is manufactured. After platinum is sputtered on the surface of the porous titania layer of the mesh structure, the second electrode section is manufactured by making the second dye (Dye1) adsorbed in the titania layer.

As the electrolyte solution used in the first and second electrode sections, a gel electrolyte solution formed by impregnating an electrolyte solution into a porous PTFE (Polytetrafluoroethylene) film (thickness: 50 μm, porosity: 80%) is used. The counter electrode is manufactured by sputtering platinum on the titanium film. These are successively laminated, in other words, the counter electrode is arranged to face the surface of the porous titania layer of the second electrode section, so that a solar cell is manufactured.

### Manufacturing Example of Dye-Sensitized Solar Cell According to Third Example of Present Embodiment

A titania paste is applied on a transparent glass substrate, and then dried at 450° C. for 30 minutes, so that a porous titania layer having a thickness of 2 μm is manufactured. The slurry having the mixture composition obtained by mixing the zinc oxide fibers having tetrapod type crystal structure with the titanium oxide fine particles is dispersed by the electrospray method on the surface of the porous titania layer. The composition ratio of the mixture of zinc oxide fibers and titania particles is adjusted to 50:50. After the dispersion process using the electrospray, the mixture is baked at a temperature of 500° C. for 30 minutes. Thereafter, a Ti film (Ti layer) is formed by a sputtering method (film thickness: 300 nm). The remaining tetrapod type crystal fibers are removed by being rinsed with dilute hydrochloric acid, so that a conductive Ti layer is formed. Further, a titania paste is applied on the conductive Ti layer, and then dried at 450° C. for 30 minutes, so that a porous titania layer having a thickness of 2 μm is manufactured. The first electrode section is manufactured by making the first dye (Dye2) adsorbed in the porous titania layer.

On the other hand, a titanium film is formed by sputtering titanium on a mesh stainless steel substrate (thickness: 25 μm) having a mesh of 20 μm diameter, and then a titanium film is further formed by an arc plasma method while introducing oxygen, so that a stainless steel mesh structure having a protected surface is manufactured. A titania paste is applied to the surface of one side of the mesh structure, and then dried at 450° C. for 30 minutes, so that a porous titania layer having a thickness of 2 μm is manufactured. The second electrode section is manufactured by making the second dye (Dye1) adsorbed in the titania layer. As the electrolyte solution, a gel electrolyte solution formed by impregnating the electrolyte solution into the porous PTFE film is used. The counter electrode is manufactured by sputtering platinum on a titanium film. These are successively laminated, in other words, the counter electrode is arranged to face the surface of the porous titania layer of the second electrode section, so that a solar cell is manufactured.

### Manufacturing Execution Example of Dye-Sensitized Solar Cell with Single Cell Having Structure Similar to Bottom Cell of Dye-Sensitized Solar Cell According to Second Example of Present Embodiment

An FTO film (surface resistance: 10Ω/□) was formed on a transparent glass substrate. Further, a titania paste was applied on the FTO film, and then dried at 450° C. for 30 minutes, so that a porous titania layer having a thickness of 2 μm was formed. The first electrode section was manufactured by making the first dye adsorbed in the porous titania layer. On the other hand, a titanium film was formed by sputtering titanium on a mesh stainless steel substrate (thickness: 25 μm) having a mesh of 20 μm diameter. Then, a titanium film was further formed by an arc plasma method while introducing oxygen, so that a stainless steel mesh structure having a protected surface was manufactured. A titania paste was applied to coat one surface of the mesh structure, and then dried at 450° C. for 30 minutes, so that a porous titania layer having a thickness of 2 μm was manufactured. After platinum was sputtered on the surface of the mesh structure, on which surface the porous titania layer was not formed, the second electrode section was manufactured by making the second dye (Dye1) adsorbed in the titania layer. As the electrolyte solution, a gel electrolyte solution formed by impregnating an electrolyte solution into a porous PTFE (Polytetrafluoroethylene) film (thickness: 50 porosity: 80%) was used. The counter electrode was manufactured by sputtering platinum on a titanium film. These were successively laminated, in other words, the counter electrode was arranged to face the surface of the porous titania layer of the second electrode section, so that a solar cell was manufactured.

In the obtained solar cell, as the performance of the cell (integrated cell) configured by electrically connecting the first electrode section with the counter electrode, the following values were obtained: Voc=0.81 V, Jsc=5.2 mA/cm², FF=0.67, and Efficiency=2.8%. Further, as the performance of the cell (single cell 1) manufactured separately from the integrated cell and configured by the first electrode section and the counter electrode, the following values were obtained: Voc=0.4 V, Jsc=5.4 mA/cm², FF=0.70, and Efficiency=1.5%. On the other hand, as the performance of the cell (single cell 2) manufactured separately from the integrated cell and configured by the second electrode section and the counter electrode, the following values were obtained: Voc=0.42 V, Jsc=4.9 mA/cm², FF=0.70, and Efficiency=1.44%. It was seen that the value of Voc of the integrated cell was increased to a value substantially equivalent to the sum of the values of Voc of the single cell 1 and the single cell 2, as compared with the case having only the single cell 1, which approximately corresponds to the conventional cell. It was seen that the peaks of the IPCE value of the integrated cell were obtained at wavelengths respectively corresponding to the peak of the IPCE value of the single cell 1 having the absorption wavelength of 500 nm and the peak of the IPCE value of the single cell 2 having the absorption wavelength of 700 nm.

### Manufacturing Execution Example of Dye-Sensitized Solar Cell with Single Cell Having Structure Similar to Bottom Cell of Dye-Sensitized Solar Cell According to Third Example of Present Embodiment

An FTO film (surface resistance: 10Ω/□) was formed on a transparent glass substrate. Further, a titania paste was applied on the FTO film, and then dried at 450° C. for 30 minutes, so that a porous titania layer having a thickness of 2 μm was formed. The first electrode section was manufactured by making the first dye adsorbed in the porous titania layer. On the other hand, a titanium film was formed by sputtering titanium on a mesh stainless steel substrate (thickness: 25 μm) having a mesh of 20 μm diameter. Then, a titanium film was further formed by an arc plasma method while introducing oxygen, so that a stainless steel mesh structure having a protected surface was manufactured. A titania paste was applied to coat one surface of the mesh structure, and then dried at 450° C. for 30 minutes, so that a porous titania layer having a thickness of 2 μm was manufactured. The second electrode section was manufactured by making the second dye adsorbed in the titania layer. As the electrolyte solution, a gel electrolyte solution formed by impregnating an electrolyte solution into a porous PTFE film (thickness: 50 μm, porosity: 80%) was used. The counter electrode was manufactured by sputtering platinum on a titanium film. These were successively laminated, in other words, the counter electrode was arranged to face the surface of the porous titania layer of the second electrode section, so that a solar cell was manufactured.

In the obtained solar cell, as the performance of the cell (integrated cell) configured by electrically connecting the counter electrode with each of the first electrode section and the second electrode section, the following values were obtained: Voc=0.4 V, Jsc=12.1 mA/cm², FF=0.60, and Efficiency=2.9%. Further, as the performance of the cell (single cell 1) manufactured separately from the integrated cell and configured by the first electrode section and the counter electrode, the following values were obtained: Voc=0.4 V, Jsc=5.4 mA/cm², FF=0.70, and Efficiency=1.5%. On the other hand, as the performance of the cell (single cell 2) manufactured separately from the integrated cell and configured by the second electrode section and the counter electrode, the following values were obtained: Voc=0.42 V, Jsc=4.9 mA/cm², FF=0.70, and Efficiency=1.44%. It was seen that the value of Jsc of the integrated cell was increased to a value substantially equivalent to the sum of the values of Jsc of the single cell 1 and the single cell 2, as compared with the case having only the single cell 1, which approximately corresponds to the conventional cell. It was seen that the peaks of the IPCE value of the integrated cell were obtained at wavelengths respectively corresponding to the peak of the IPCE value of the single cell 1 having the absorption wavelength of 500 nm and the peak of the IPCE value of the single cell 2 having the absorption wavelength of 700 nm.

Manufacturing Execution Example of Dye-Sensitized Solar Cell with Single Cell Having Structure Similar to Top Cell of Dye-Sensitized Solar Cell According to Second or Third Example of Present Embodiment

A titania paste (1 layer of HT paste, 5 layers of D paste: made by Solaronix Co., Ltd.) was applied on a glass substrate to have a thickness of 20 μm, and was then baked at 500° C. for 30 minutes, so that a titania (titania layer, porous semiconductor layer) was manufactured. A slurry having a mixture composition obtained by mixing zinc oxide fibers having tetrapod type crystal structure (product name: Panatetra, average fiber length in fiber portion: about 10 μm, average fiber diameter: about 1 μm, made by Amtec Co., Ltd.) with titanium oxide fine particles (product name: AEROXIDE (registered trademark) TiO2P25, average particle diameter of primary particle: about 20 nm, aggregate size: 200 nm, made by Japan Aerosil Co., Ltd.) was dispersed by an electrospray method on the titania surface of the baked substrate. The composition ratio of the mixture of zinc oxide fibers and titania particles in the mixture was adjusted to 50:50. After the dispersion process using the electrospray, the mixture was baked at a temperature of 500° C. for 30 minutes. Thereafter, a Ti film (Ti layer) was formed by a sputtering method (film thickness: 300 nm). The remaining tetrapod type crystal fibers were removed by being rinsed with dilute hydrochloric acid, so that a conductive Ti layer was formed.

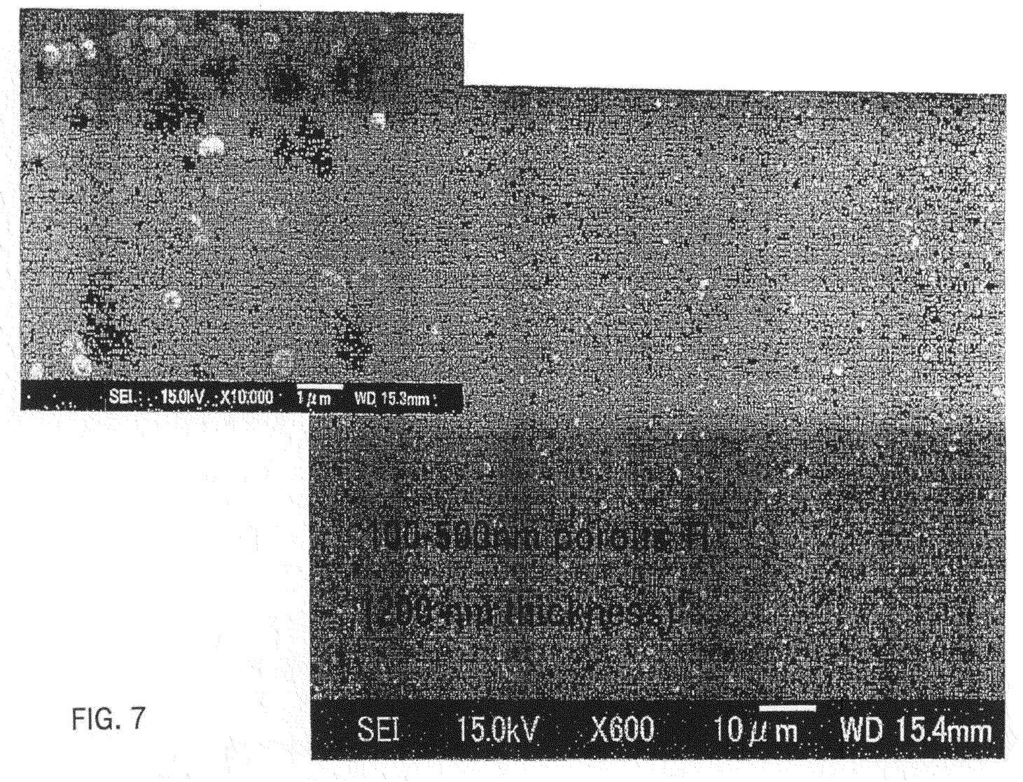

An SEM photograph of the Ti film obtained at this time is shown in FIG. 7. It is possible to observe a group of deep hole-like through holes (dark portions in FIG. 7) formed in the Ti film, and a group of porous semiconductor particles (white particle portions or grey particle portions having the same color as the base layer in FIG. 7) penetrating the Ti film to expose the tip of the particles.

Then, the substrate with the Ti layer formed thereon was immersed in 0.05 wt % of a dye solution (black dye, acetonitrile: t-butyl alcohol=1:1: made by SOLARONIX Co., Ltd.) for 20 hours.

As the material of the counter electrode, a fluorine-doped tin oxide glass (made by SOLARONIX Co., Ltd.) subjected to platinum sputtering treatment was used. The substrate with the Ti layer formed thereon and the counter electrode were sealed with spacers (Himilan made by Mitsui Du-Pont Polychemical Co., Ltd.) having a thickness of 50 μm. An electrolytic solution made of an acetonitrile solution containing iodine 40 mM, LiI 500 mM, and t-Butylpyridine 580 mM was injected in the obtained cell, so that a cell (unit cell) of 5 mm squares was manufactured.

When the performance of the manufactured dye-sensitized solar cell was measured and evaluated by using a solar simulator to irradiate the solar cell with pseudo sunlight (AM 1.5) with an intensity of 100 mW/cm², the efficiency of 10.8% was obtained.

### FIG. 1

### #1 INCIDENT LIGHT

### FIG. 2

### #1 INCIDENT LIGHT

### FIG. 4

### #1 INCIDENT LIGHT

### FIG. 6

#1 INCIDENT LIGHT

What is claimed is:

1. A dye-sensitized solar cell comprising, in order from the light incident side: an anode substrate; a first dye-carrying porous oxide semiconductor layer; a first electrolyte layer; an electrolyte redox catalyst layer; a second dye-carrying porous oxide semiconductor layer; a porous support layer; a second electrolyte layer; and a cathode substrate.

2. The dye-sensitized solar cell according to claim 1, comprising: a transparent substrate in place of the anode substrate; and further a porous conductive metal layer arranged either in the inside of the first dye-carrying porous oxide semiconductor layer or between the first dye-carrying porous oxide semiconductor layer and the first electrolyte layer, wherein the porous support layer is provided either in the inside of the second dye-carrying porous oxide semiconductor layer or on one of the sides of the second dye-carrying porous oxide semiconductor layer.

3. A dye-sensitized solar cell comprising, in order from the light incident side: an anode substrate; a first dye-carrying porous oxide semiconductor layer; a first electrolyte layer; a second dye-carrying porous oxide semiconductor layer; porous conductive metal support layer; a second electrolyte layer; and a cathode substrate.

4. The dye-sensitized solar cell according to claim 3, comprising: a transparent substrate in place of the anode substrate; and further a porous conductive metal layer arranged either in the inside of the first dye-carrying porous oxide semiconductor layer or between the first dye-carrying porous oxide semiconductor layer and the first electrolyte layer, wherein the porous conductive metal support layer is provided either in the inside of the second dye-carrying porous oxide semiconductor layer or on one of the sides of the second dye-carrying porous oxide semiconductor layer.

5. The dye-sensitized solar cell according to one of claim 1 and claim 3, wherein a conductor layer configuring the anode substrate includes a porous conductive metal layer.

6. The dye-sensitized solar cell according to one of claim 2 and claim 4, wherein the porous conductive metal layer has numerous through holes formed irregularly and having a deep hole shape, and numerous porous semiconductor particles penetrating the porous conductive metal layer so as to be in contact with the layers on both sides of the porous conductive metal layer.

7. The dye-sensitized solar cell according to any one of claim 1 to claim 4, wherein the dye carried by the second dye-carrying porous oxide semiconductor layer has a light absorption wavelength longer than a light absorption wavelength of the dye carried by the first dye-carrying porous oxide semiconductor layer.
